(19) United States
(12) Patent Application Publication
(10) Pub. No.: US 2026/0353733 A1
(43) Pub. Date: Nov. 5, 2026

(54) HIGH ELECTRON MOBILITY TRANSISTOR

(71) Applicant: SONY SEMICONDUCTOR SOLUTIONS CORPORATION, KANAGAWA (JP)

(72) Inventors: MIKIHIRO TAKETOMO, KANAGAWA (JP); KUNIHIKO MORI, KANAGAWA (JP); MASASHI YANAGITA, KANAGAWA (JP)

(21) Appl. No.: 19/104,994

(22) PCT Filed: Aug. 31, 2022
(86) PCT No.: PCT/JP2022/032732

§ 371 Date: Feb. 19, 2025

(51) Int. Cl. H10D 62/60; H10D 30/47; H10D 62/824; H10D 64/23; H10D 64/27

(52) U.S. Cl. CPC H10D 62/60; H10D 30/475; H10D 62/824; H10D 64/251; H10D 64/411

(57) ABSTRACT

A high electron mobility transistor according to an embodiment of the present technology includes a heterojunction structure including a GaN channel layer in which two recesses are formed with a predetermined interval therebetween. This high electron mobility transistor further includes: a regrowth layer formed to fill each recess; a source-drain electrode in ohmic contact with the regrowth layer; and a gate electrode disposed via a gate insulating film on a section of the GaN channel layer between the two recesses. The regrowth layer is configured to include a first GaN layer doped with Si at a relatively high concentration and one or a plurality of second GaN layers that is doped with Si at a relatively low concentration and is formed in the first GaN layer.

### TECHNICAL FIELD

The present technology relates to a high electron mobility transistor.

### BACKGROUND ART

A GaN-based high electron mobility transistor has a wide band gap as well as an extremely large dielectric breakdown voltage and saturation electron speed, and has attracted attention for having potential for increasing the output and speed of electronic devices (see, for example, Patent Literature 1).

### CITATION LIST

### Patent Literature

Patent Literature 1: Japanese Unexamined Patent Application Publication No. 2017-059671

### SUMMARY OF THE INVENTION

Incidentally, there is a call for further enhancement of an operating characteristic of a GaN-based high electron mobility transistor. Therefore, it is desirable to provide a high electron mobility transistor that enables further enhancement in an operating characteristic.

A high electron mobility transistor according to an embodiment of the present technology has a heterojunction structure including a GaN channel layer in which two recesses are formed with a predetermined interval therebetween. This high electron mobility transistor further has: a regrowth layer formed to fill each recess; a source-drain electrode in ohmic contact with the regrowth layer; and a gate electrode disposed via a gate insulating film on a section of the GaN channel layer between the two recesses. The regrowth layer includes a first GaN layer doped with Si at a relatively high concentration and one or a plurality of second GaN layers that is doped with Si at a relatively low concentration and is formed in the first GaN layer.

### BRIEF DESCRIPTION OF THE DRAWINGS

FIG. 1 is a diagram illustrating a cross-sectional configuration example of a high electron mobility transistor according to an embodiment of the present technology.

FIG. 2 is an enlarged diagram illustrating a portion of the high electron mobility transistor of FIG. 1.

FIG. 3 is a diagram illustrating an example of a Si concentration profile of a regrowth layer measured by SIMS.

FIG. 4 is a diagram illustrating an example of Si and C concentration profiles of a GaN layer with a high Si concentration.

FIG. 5 is a diagram illustrating a cross-sectional configuration example of a test transistor.

FIG. 6 is a diagram illustrating a planar configuration example of a test module provided with a plurality of the test transistors of FIG. 5.

FIG. 7 is a diagram illustrating an example of annealing temperature dependence of a contact resistance.

FIG. 8 is a diagram illustrating an example of annealing temperature dependence of a sheet resistance of the regrowth layer.

FIG. 9 is a diagram illustrating an example of a manufacturing process of the high electron mobility transistor of FIG. 1.

FIG. 10 is a diagram illustrating an example of the manufacturing process that continues to FIG. 10.

FIG. 11 is a diagram illustrating an example of the manufacturing process that continues to FIG. 11.

FIG. 12 is a diagram illustrating a modification example of a cross-sectional configuration of the high electron mobility transistor of FIG. 2.

FIG. 13 is a diagram illustrating an example of a Si concentration profile of the regrowth layer measured by SIMS.

FIG. 14 is a diagram illustrating a circuit configuration example of an antenna switch circuit.

FIG. 15 is a diagram illustrating a circuit configuration example of a wireless communication apparatus.

FIG. 16 is a diagram illustrating a circuit configuration example of a power amplifier module.

### MODES FOR CARRYING OUT THE INVENTION

Hereinbelow, an embodiment for carrying out the present technology is described in detail with reference to the drawings.

### 1. Embodiment

### Configuration

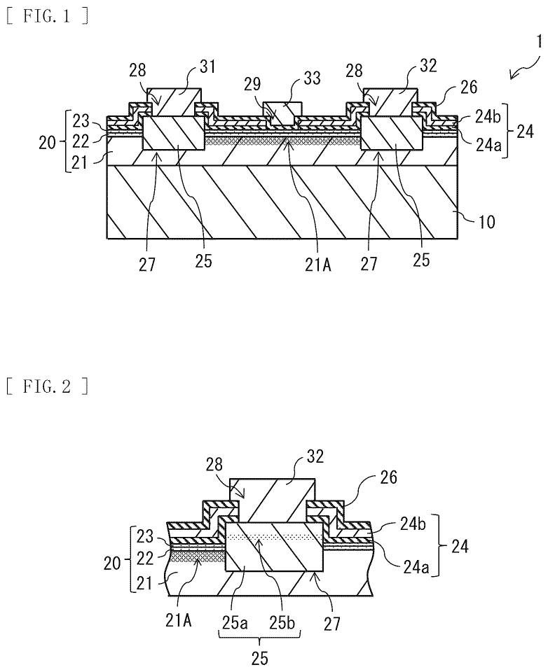

A high electron mobility transistor (HEMT) of an embodiment of the present technology will be described. FIG. 1 illustrates a schematic configuration example of a HEMT 1 of the present embodiment. The HEMT 1 has what is called a heterojunction structure in which a buffer layer 22 and a barrier layer 23 are stacked on a GaN channel layer 21. In the HEMT 1, electrons accumulate at a high concentration in an area of the GaN channel layer 21 adjacent to a heterojunction interface, and what is called a two-dimensional electron gas region 21A (2DEG: two-dimensional electron gas) is formed. This two-dimensional electron gas region 21A exhibits high electron mobility. In particular, the barrier layer 23 stacked on the GaN channel layer 21 induces an extremely high electron concentration on a surface of the GaN channel layer 21.

The HEMT 1 includes, for example, the GaN channel layer 21, the buffer layer 22, and the barrier layer 23, in the foregoing order, on a substrate 10, as illustrated in FIG. 1.

The substrate 10 is, for example, a Si substrate. In a case where a buffer layer including an Al-containing group III nitride semiconductor, such as AIN or AlGaN, is provided between the GaN substrate 10 and the GaN channel layer 21, the substrate 10 may be, for example, a SiC or sapphire substrate.

The GaN channel layer 21 is a layer formed by performing epitaxial growth on the substrate 10 or the above-described buffer layer. The GaN channel layer 21 includes GaN. The buffer layer 22 is a layer formed by performing epitaxial growth on the GaN channel layer 21. The buffer layer 22 includes, for example, AIN or AlGaN. The barrier layer 23 is a layer formed by performing epitaxial growth on the buffer layer 22. The barrier layer 23 includes AlₓGa_{y}InₓN (x+y+z=1, x≥0, y≥0, z≥0). In a case where the HEMT 1 operates, the two-dimensional electron gas region 21A develops in the area of the GaN channel layer 21 adjacent to the heterojunction interface, by which a channel region is formed in the area of the GaN channel layer 21 adjacent to the heterojunction interface. Here, a carrier concentration of the two-dimensional electron gas region 21A is, for example, 8×10¹² cm⁻² or greater.

A semiconductor layer including the GaN channel layer 21, the buffer layer 22, and the barrier layer 23 (hereinafter, “semiconductor layer 20”) has a recessed section (recess) 27 at a section that is opposite to each of below-described source-drain electrodes 31 and 32. The recess 27 has a depth that reaches the GaN channel layer 21. In other words, the semiconductor layer 20 (GaN channel layer 21) has two recesses 27 with a predetermined interval therebetween. The recess 27 is formed by dry etching, for example, on the semiconductor layer 20. The depth of the recess 27 is, for example, about 30 nm.

As illustrated in FIG. 1, the HEMT 1 includes, for example, a regrowth layer 25 that is formed to fill the recess 27 and protrude from an outermost surface of the semiconductor layer 20. A thickness of the regrowth layer 25 is, for example, about 80 nm. As illustrated in FIG. 2, the regrowth layer 25 is, for example, in contact with an edge of the two-dimensional electron gas region 21A (section exposed on a side of the recess 27). The regrowth layer 25 is a layer formed by using a predetermined deposition method. The regrowth layer 25 is formed by a method that enables deposition at a lower temperature than a growth temperature of the barrier layer 23.

As illustrated in FIG. 2, the regrowth layer 25 includes, for example, a GaN layer 25a doped with Si (n-type impurity) at a relatively high concentration and a GaN layer 25b that is doped with Si (n-type impurity) at a relatively low concentration and is formed within the GaN layer 25a. The GaN layer 25a is formed at a section (depth) in contact with at least the edge of the two-dimensional electron gas region 21A (section exposed on the side of the recess 27). The GaN layer 25a is further formed at a section in contact with below-described source-drain electrodes 31 and 32 (that is, on the outermost surface of the regrowth layer 25). The GaN layer 25b is formed in the regrowth layer 25 at a depth shallower than the two-dimensional electron gas region 21A and deeper than the outermost surface of the regrowth layer 25.

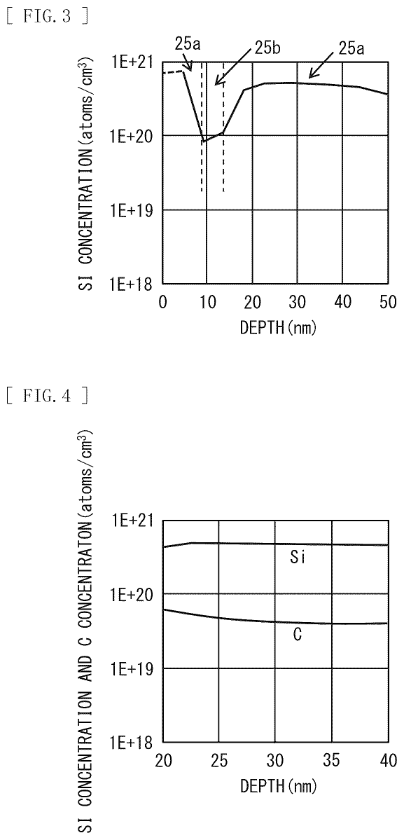

As illustrated in FIG. 3, the GaN layer 25a is, for example, an n-type GaN layer doped with Si at a concentration of 1×10²⁰ cm⁻³ or greater. As illustrated in FIG. 3, the GaN layer 25b is, for example, an n-type GaN layer doped with Si at a concentration of 1×10¹⁸ cm⁻³ or greater and below 1×10²⁰ cm⁻³. A thickness of the GaN layer 25b is, for example, 5 nm or greater. A ratio of a maximum concentration of Si doped in the GaN layer 25a to a minimum concentration of Si doped in the GaN layer 25b is, for example, 7:1 or greater. A dashed line in FIG. 3 means that a value is inaccurate due to an effect, such as contamination, during measurement.

A carrier density of the regrowth layer 25 is, for example, 1×10²⁰ (cm⁻³) or greater. A sheet resistance of the regrowth layer 25 is, for example, 300 (Ω·× sq) or smaller. A contact resistance of the regrowth layer 25 is, for example, below 0.3 (Ω·mm). As illustrated in FIG. 4, a composition ratio (Si/C) of Si to carbon (C) in the GaN layer 25a is, for example, 70 or smaller. In a case where the carrier concentration of the two-dimensional electron gas region 21A, a carrier concentration of the regrowth layer 25, and the sheet resistance and contact resistance of the regrowth layer 25 satisfy the above-described conditions in the HEMT 1, an on-resistance of the HEMT 1 is, for example, 0.7(Ω·mm) or smaller. As described above, according to the present embodiment, it is possible to achieve a high-quality HEMT in which the carrier concentration of the two-dimensional electron gas region 21A is sufficiently high, the sheet resistance and contact resistance of the regrowth layer 25 are low, and the on-resistance is low.

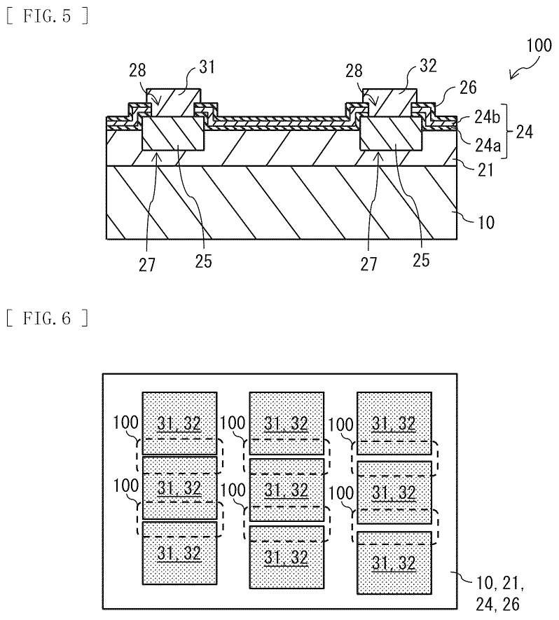

The sheet resistance Rs and the contact resistance Rc of the regrowth layer 25 are measured, for example, using a test transistor 100 illustrated in FIG. 5 that does not have a gate electrode. For example, as illustrated in FIG. 6, a plurality of the test transistors 100 that has a pair of the source-drain electrodes 31 and 32, each having a different interval therebetween, is formed on the substrate 10. In a case where these test transistors 100 are energized, on the basis of measurements obtained therefrom, it is possible to calculate the sheet resistance Rs and contact resistance Rc of the regrowth layer 25.

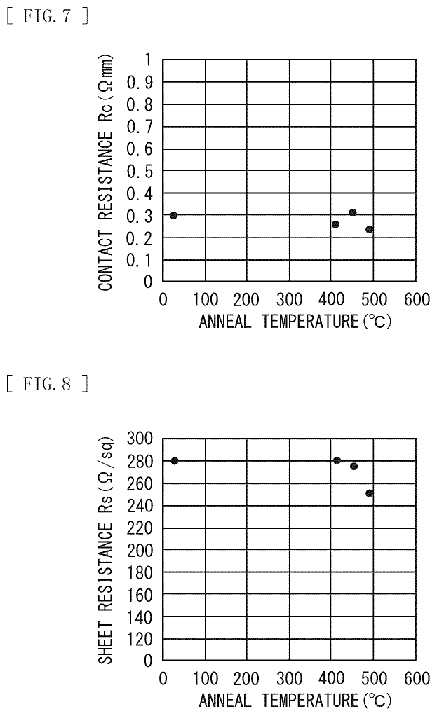

FIG. 7 illustrates a value of the contact resistance Rc at varied annealing temperatures in a case of manufacturing a plurality of the test transistors 100 illustrated in FIG. 6. It is possible to recognize that even in a case where the annealing temperature is as high as 500 °C, the contact resistance Rc is as low as 0.3 Ω·mm.

FIG. 8 illustrates a value of the sheet resistance Rs at different annealing temperatures in a case of manufacturing the plurality of the test transistors 100 of FIG. 6. Since the carrier density of the regrowth layer 25 is 5×10²⁰ cm⁻³, it is possible to acknowledge that the sheet resistance Rs is as low as 250 Q/sq even in a case where the annealing temperature is as high as 500 °C. It is possible to recognize from the foregoing that setting the process temperature to 500 °C or lower enables the sheet resistance Rs to be set to a low value.

As illustrated in FIG. 1, the HEMT 1 includes, for example, an insulating layer 24 and a gate insulating film 26 on the semiconductor layer 20. The insulating layer 24 is, for example, a stack body in which an Al₂O₃ layer 24a and a SiO₂ layer 24b are stacked in the foregoing order from a side of the semiconductor layer 20. The gate insulating film 26 includes, for example, a stack body of Al₂O₃/HfO₂. The insulating layer 24 and the gate insulating film 26 have openings 28 in portions of sections of the semiconductor layer 20 that are opposite to upper surfaces of the two regrowth layers 25. The insulating layer 24 and the gate insulating film 26 further include an opening 29 in a portion of a section of the semiconductor layer 20 that is opposite to a below-described gate electrode 33.

As illustrated in FIG. 1, the HEMT 1 includes, for example, the source-drain electrode 31 in one of the openings 28 and the source-rain electrode 32 in the other opening 28. As illustrated in FIG. 1, the HEMT 1 further includes, for example, the gate electrode 33 in the opening 29. The source-drain electrodes 31 and 32 are in ohmic contact with the regrowth layer 25 via the opening 28. The source-drain electrodes 31 and 32 are disposed on the regrowth layer 25. The gate electrode 33 is in contact with the gate insulating film 26 via the opening 29. The gate electrode 33 is disposed via the gate insulating film 26 on a section of the GaN channel layer 21 between the two recesses 27. The source-drain electrodes 31 and 32 include, for example, a Ti/Al/Ni/Au stack body. The gate electrode 33, for example, includes a Ni/Au stack body.

### Manufacturing Method

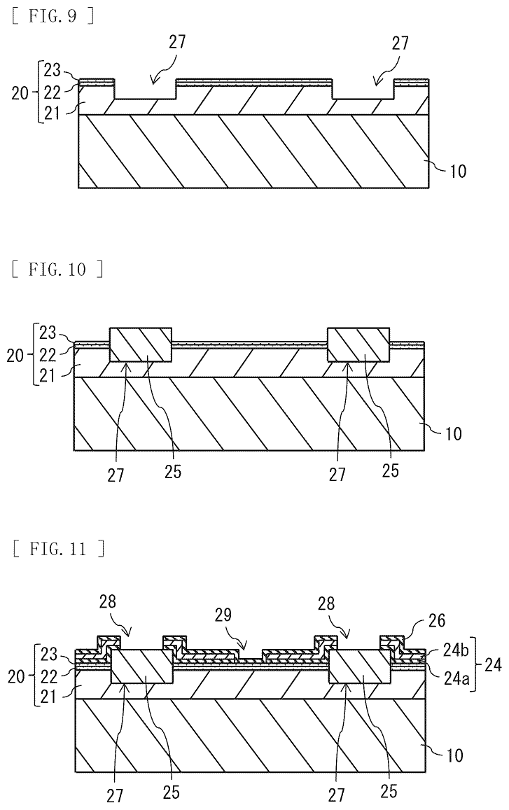

Next, a manufacturing method of the HEMT 1 according to the present embodiment will be described. FIGS. 9 to 11 illustrate an example of a manufacturing procedure of the HEMT 1 according to the present embodiment.

First, the semiconductor layer 20 including the GaN channel layer 21, the buffer layer 22, and the barrier layer 23 is formed on the substrate 10 (FIG. 9). Next, the recess 27 is formed at a predetermined section in the semiconductor layer 20 (FIG. 9). At this time, the recess 27 is formed to a depth where the GaN channel layer 21 is exposed at a bottom surface of the recess 27.

Next, for example, the regrowth layer 25 is formed on an entire surface including the recess 27. At this time, the regrowth layer 25 is deposited at a lower temperature than the growth temperature of the barrier layer 23. It is thereby possible to prevent the barrier layer 23 from degrading. Subsequently, a section of the regrowth layer 25 in contact with the barrier layer 23 is removed by wet etching. It is thereby possible to form the regrowth layer 25 in a configuration where the regrowth layer 25 fills the recess 27 and protrudes from an outermost surface of the semiconductor layer 20 (FIG. 10).

Next, after forming the insulating layer 24 and the gate insulating film 26 on the semiconductor layer 20, the openings 28 and 29 are formed at predetermined sections in the insulating layer 24 and the gate insulating film 26 by, for example, wet etching (FIG. 11). Thereafter, for example, the source-drain electrodes 31 and 32 and the gate electrode 33 are formed using, inter alia, liftoff. In this way, the HEMT 1 according to the present embodiment is manufactured.

### Effects

Next, effects of the HEMT 1 according to the present embodiment will be described.

A GaN-based device is being developed toward application to a compact and high-performance power device and a high-frequency device because a GaN-based device is characterized by high breakdown voltage, high heat resistance, high saturation electron speed, and high channel electron concentration. In next-generation mobile communication systems (5G and 6G), a millimeter-wave signal is expected to be used due to data rate enhancement. In a millimeter wave band, where spatial attenuation is large, high power output is required, and a power amplifier that achieves both high frequency and high efficiency is therefore required. Due to the aforementioned characteristics of GaN, a GaN-based device is beginning to be used as a high-output and high-frequency semiconductor device instead of a device including a GaAs-based material.

In general, in a GaN-based high electron mobility transistor (hereinafter, “GaN-HEMT”), instead of fabricating an electrode on a GaN film to achieve source-drain ohmic contact, a recess configuration is created for a channel layer to bring a regrowth layer that is a conductor layer into direct contact with a 2DEG region. This type of configuration enables reduction of a contact resistance.

However, in a case where a process temperature for regrowth layer formation is higher than a growth temperature of a barrier layer, the barrier layer is degraded. As well, in a case of increasing a thickness of a regrowth layer, a degree of crystallinity in the regrowth layer decreases, and an operating characteristic of an HEMT deteriorates.

On the other hand, according to the present embodiment, the regrowth layer 25 is provided that includes the GaN layer 25a doped with Si at a relatively high concentration and the GaN layer 25b that is doped with Si at a relatively low concentration and is formed within the GaN layer 25a. Here, by depositing the regrowth layer 25 at a lower temperature than the deposition temperature of the barrier layer 23, it is possible to prevent the barrier layer 23 from degrading and achieve resistance reduction without degrading crystallinity of the regrowth layer 25. As a result, it is possible to achieve the HEMT 1 with an excellent operating characteristic.

### 2. Modification Example

Next, a modification example of the HEMT 1 according to the above embodiment will be described. Hereinbelow, a common reference numeral will be assigned to a common component, and a description of the common component will be omitted as appropriate.

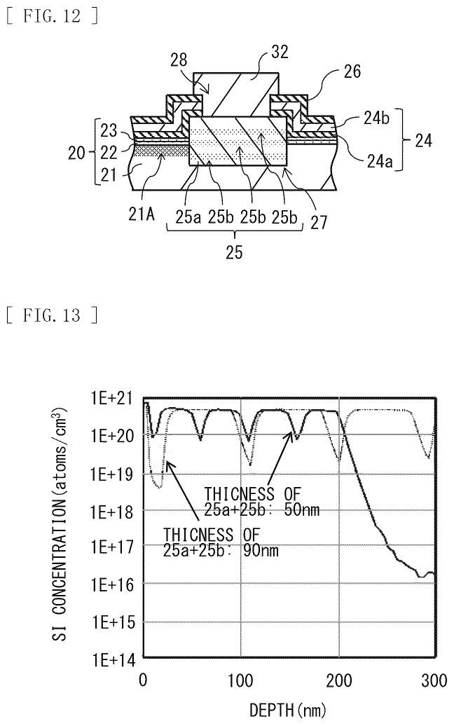

In the above embodiment, as illustrated in FIG. 12, the regrowth layer 25 may include, for example, the GaN layer 25a and a plurality of the GaN layers 25b that is formed within the GaN layer 25a.

FIG. 13 illustrates an example of a Si concentration profile of the regrowth layer 25. In this case, the regrowth layer 25 is formed by alternately forming the GaN layer 25a and the GaN layer 25b, forming four pairs of the GaN layer 25a and the GaN layer 25b, and further forming the GaN layer 25a on an outermost layer. In FIG. 13, a solid line represents an example of a Si concentration profile in a case where a thickness of the pair of the GaN layer 25a and the GaN layer 25 is set to about 50 nm. In FIG. 13, a dashed line represents an example of a Si concentration profile in a case where a thickness of the pair of the GaN layer 25a and the GaN layer 25 is set to about 90 nm.

The solid and dashed lines each indicate that a portion of the GaN layer 25b doped with Si at a relatively low concentration exists within 20 nm from the outermost surface of the regrowth layer 25 (interface between the regrowth layer 25 and the source-drain electrodes 31 and 32). Therefore, a portion of the GaN layer 25b is always present at a depth within 20 nm from the outermost surface of the regrowth layer 25 (interface between the regrowth layer 25 and the source-drain electrodes 31 and 32).

In the solid line, a specific resistance of the pair of the GaN layer 25a and the GaN layer 25b is, for example, 5.7×10⁻⁴ Ωcm. In the dashed line, a specific resistance of the pair of the GaN layer 25a and the GaN layer 25b is, for example, 7.6×10⁻⁴ Ωcm. It is possible to recognize from the foregoing that, even in a case where the GaN layer 25b doped with Si at a low concentration is provided, the specific resistance of the pair of the GaN layer 25a and the GaN layer 25b is sufficiently low, indicating that the GaN layer 25b does not cause a defect in an electrical property of the regrowth layer 25. One reason for this is that Si in the GaN layer 25a doped with Si at a high concentration is substitutionally dissolved in the Ga site and acts as a dopant, and electrical property degradation, such as neutral impurity scattering, is therefore not caused by Si outside the site. It is also possible to control a Si composition ratio of the GaN layer 25a to the GaN layer 25b by changing a thickness of the GaN layer 25a.

In the present modification example, a plurality of the GaN layers 25b is provided in the regrowth layer 25. Even in this case, formation of the regrowth layer 25 with a low contact resistance and high quality is possible. As a result, it is possible to achieve the HEMT 1 with an excellent operating characteristic.

### 3. Application Example

Next, application examples of the HEMT 1 according to the above embodiment and the modification example will be described. Hereinbelow, a common reference numeral will be assigned to a common component, and a description of the common component will be omitted as appropriate.

### Application Example A

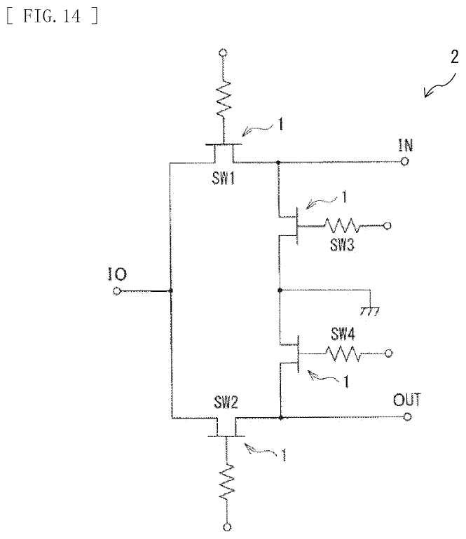

FIG. 14 illustrates an example of an antenna switch circuit 2. The antenna switch circuit 2 is used in a mobile communication system for, inter alia, a cellular phone, and includes, for example, a first terminal IN, a second terminal IO, a third terminal OUT, a first switching device SW1, and a second switching device SW2.

A transmitted signal is to be input to the first terminal IN. The second terminal IO is connected to an antenna. The third terminal OUT outputs a received signal received by the antenna. The first switching device SW1 is connected between the first terminal IN and the second terminal IO. The second switching device SW2 is connected between the second terminal IO and the third terminal OUT. The first switching device SW1, the second switching device SW2, or both include the HEMT 1 according to the above embodiment and the modification example thereof.

A third switching device SW3 is connected between the first terminal IN and a power supply (ground in this example). A fourth switching device SW4 is connected between the third terminal OUT and the power supply (ground in this example). The third switching device SW3, the fourth switching device SW4, or both include the HEMT 1 according to the above embodiment and the modification example thereof.

In the antenna switch circuit 2, in a case of transmission, that is, in a case where a transmitted signal is output from a transmission system of a wireless communication apparatus to the antenna, the first switching device SW1 and the fourth switching device SW4 are in a conducting state, and the second switching device SW2 and the third switching device SW3 are in a non-conducting state. In this case, the transmitted signal is input from the first terminal IN and output to the second terminal IO via the first switching device SW1.

In a case of reception, that is, in a case where a signal received by the antenna is input to a reception system of the wireless communication apparatus, the first switching device SW1 and the fourth switching device SW4 are in a non-conducting state, and the second switching device SW2 and the third switching device SW3 are in a conducting state. In this case, the received signal received by the antenna is input from the second terminal IO and output to the third terminal OUT via the second switching device SW2.

Thus, in the present application example, the HEMT 1 according to the above embodiment and the modification example thereof is used. This enables enhancement of power resistance.

### Application Example B

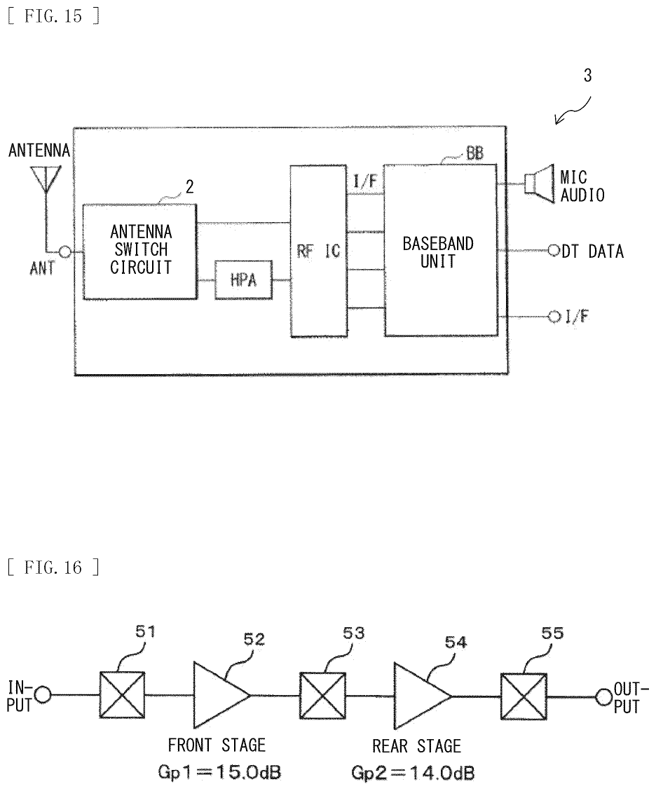

FIG. 15 illustrates an example of a wireless communication apparatus 3. The wireless communication apparatus 3 is, for example, a multifunctional cellular phone system for, inter alia, audio or data communication or LAN connection. The wireless communication apparatus 3 includes, for example, an antenna ANT, the antenna switch circuit 2, a high-power amplifier HPA, a radio frequency integrated circuit RFIC (Radio Frequency Integrated Circuit), a baseband unit BB, an audio output unit MIC, a data output unit DT, and an interface unit I/F (for example, wireless LAN (W-LAN; Wireless Local Area Network) or Bluetooth (registered trademark)). The antenna switch circuit 2 has, for example, the configuration described in FIG. 14. The radio frequency integrated circuit RFIC and the baseband unit BB are connected by the interface unit I/F.

In the wireless communication apparatus 3, in a case of transmission, that is, in a case where a transmitted signal is output from a transmission system of the wireless communication apparatus 3 to the antenna ANT, a transmitted signal output from the baseband unit BB is output via the radio frequency integrated circuit RFIC, the high-power amplifier HPA, and the antenna switch circuit 2 to the antenna ANT.

In a case of reception, that is, in a case where a signal received by the antenna ANT is input to a reception system of the wireless communication apparatus 3, the received signal is input to the baseband unit BB via the antenna switch circuit 2 and the radio frequency integrated circuit RFIC. The signal processed in the baseband unit BB is output from an output section, such as, the audio output unit MIC, the data output unit DT, or the interface unit I/F.

Thus, in the present application example, the HEMT 1 according to the above embodiment and the modification example thereof is used. This enables enhancement of power resistance.

### Application Example C

FIG. 16 illustrates an example of a power amplifier module 4. In the power amplifier module 4, power amplifiers configured to include the HEMT 1 according to the above embodiment and the modification example thereof are connected in multiple stages on a single substrate. FIG. 16 illustrates a circuit configuration of the power amplifier module 4 in compliance with W-CDMA specification requirements.

As illustrated in FIG. 16, the power amplifier module 4 includes an input matching circuit 51, a front-stage power amplifier 52, a middle matching circuit 53, a rear-stage power amplifier 54, and an output matching circuit 55. A gain of the front-stage power amplifier 52 is set to be 15.0 dB, and a gain of the rear-stage power amplifier 54 is set to be 14.0 dB.

In addition, the front-stage power amplifier 52 and the rear-stage power amplifier 54 are configured to include, as an amplifying device, the HEMT 1 according to the above embodiment and the modification example thereof. The power amplifiers 52 and 54 each achieve the above-described different gains by varying a distance Lfp between a gate electrode and a field plate electrode.

Thus, in the present application example, the HEMT 1 according to the above embodiment and the modification example thereof is used. This enables enhancement of power resistance.

Although the present technology has been described with reference to the embodiments, modification examples, and application examples, the present technology is not limited to the above embodiments and the like, and various modifications are possible. It should be noted that the effects described in this specification are only exemplified. Effects of the present technology are not limited to the effects described herein. The present technology may have effects other than the effects described herein.

For example, Si is used as a dopant in the above embodiment and the like, but Ge or Sn may be used.

Moreover, for example, the present technology may also be configured as follows.

(1)

A high electron mobility transistor including:
a heterojunction structure including a GaN channel layer having two recesses with a predetermined interval therebetween;
a regrowth layer formed to fill each of the recesses; a source-drain electrode in ohmic contact with the regrowth layer; and
a gate electrode disposed via a gate insulating film on a section of the GaN channel layer between the two recesses,
in which the regrowth layer includes
a first GaN layer doped with Si at a relatively high concentration, and
one or a plurality of second GaN layers that is doped with Si at a relatively low concentration and is formed within the first GaN layer.
   (2)

The high electron mobility transistor according to (1), in which the first GaN layer is provided at a position where the first GaN layer is in contact with a two-dimensional electron gas region formed in the GaN channel layer.

(3)

The high electron mobility transistor according to (1) or (2), in which a ratio of a maximum concentration of Si doped in the first GaN layer to a minimum concentration of Si doped in the second GaN layer is 7:1 or greater.

(4)

The high electron mobility transistor according to any one of (1) to (3), in which a portion of at least one of the second GaN layers included in the regrowth layer is present at a depth of 20 nm or less from an interface between the regrowth layer and the source-drain electrode.

1. A high electron mobility transistor comprising:
a heterojunction structure including a GaN channel layer having two recesses with a predetermined interval therebetween;
a regrowth layer formed to fill each of the recesses;
a source-drain electrode in ohmic contact with the regrowth layer; and
a gate electrode disposed via a gate insulating film on a section of the GaN channel layer between the two recesses,
wherein the regrowth layer includes
a first GaN layer doped with Si at a relatively high concentration, and
one or a plurality of second GaN layers that is doped with Si at a relatively low concentration and is formed within the first GaN layer.

2. The high electron mobility transistor according to claim 1, wherein the first GaN layer is provided at a position where the first GaN layer is in contact with a two-dimensional electron gas region formed in the GaN channel layer.

3. The high electron mobility transistor according to claim 1, wherein a ratio of a maximum concentration of Si doped in the first GaN layer to a minimum concentration of Si doped in the second GaN layer is 7:1 or greater.

4. The high electron mobility transistor according to claim 1, wherein a portion of at least one of the second GaN layers included in the regrowth layer is present at a depth of 20 nm or less from an interface between the regrowth layer and the source-drain electrode.
